(19) United States
(12) Patent Application Publication
(10) Pub. No.: US 2020/0189018 A1
(43) Pub. Date: Jun. 18, 2020

(54) APPARATUS AND METHOD FOR AUTOMATED SOLDERING PROCESS

(71) Applicant: Lear Corporation, Southfield, MI (US)

(72) Inventors: Michael A. FISHER, Ferndale, MI (US); Michael HANS, Novi, MI (US); John M. SEMBER, Southfield, MI (US)

(21) Appl. No.: 16/220,085

(22) Filed: Dec. 14, 2018

(51) Int. Cl. B23K 3/06; H02K 11/30; H05K 3/34

(52) U.S. Cl. CPC B23K 3/0607; H05K 3/34; H02K 11/30

(57) ABSTRACT

In at least one embodiment, an apparatus for an automated soldering process is provided. The apparatus includes a stepper motor to provide solder and a hot end including a casing to heat the solder and to provide liquified solder to a terminal and to an exposed portion of a wire. The apparatus includes a terminal fixture to support the terminal and the exposed portion of a wire while the hot end provides the liquified solder to the terminal and to the exposed portion of the wire. The apparatus includes a first heating device to heat the terminal and the exposed portion of the wire to enable a flow of the liquified solder onto the terminal and the exposed portion of the wire.

### TECHNICAL FIELD

Aspects disclosed herein generally relate to an apparatus and method for an automated soldering process. For example, aspects disclosed herein generally provide an apparatus and method that utilizes a hot end (or solder head) to apply solder to a wire and terminal connection. These aspects and others will be discussed in more detail herein.

### BACKGROUND

U.S. Publication No. 2016/0129643 to Mark et al. discloses three-dimensional printers and reinforced filaments, and various methods of use thereof. In one embodiment, a void free reinforced filament is fed into a conduit nozzle. The reinforced filament includes a core, which may be continuous or semi-continuous, and a matrix material surrounding the core. The reinforced filament is heated to a temperature greater than a melting temperature of the matrix material and less than a melting temperature of the core prior to dragging the filament from the conduit nozzle.

### SUMMARY

In at least one embodiment, an apparatus for an automated soldering process is provided. The apparatus includes a stepper motor to provide solder and a hot end including a casing to heat the solder and to provide liquified solder to a terminal and to an exposed portion of a wire. The apparatus includes a terminal fixture to support the terminal and the exposed portion of a wire while the hot end provides the liquified solder to the terminal and to the exposed portion of the wire. The apparatus includes a first heating device to heat the terminal and the exposed portion of the wire to enable the flow of the liquified solder onto the terminal and the exposed portion of the wire.

In at least another embodiment, an apparatus for an automated soldering process is provided. The apparatus includes a stepper motor to provide solder and a hot end to heat the solder and to provide liquified solder to a terminal and to an exposed portion of a wire. The apparatus includes a terminal fixture to support the terminal and the exposed portion of a wire while the hot end provides the liquified solder to the terminal and to the exposed portion of the wire. The apparatus includes a first heating device to heat the terminal and the exposed portion of the wire to enable the flow of the liquified solder onto the terminal and the exposed portion of the wire.

In at least another embodiment, an apparatus for an automated soldering process is provided. The apparatus includes a hot end to heat the solder and to provide liquified solder to a terminal and to an exposed portion of a wire. The apparatus includes a terminal fixture to support the terminal and the exposed portion of a wire while the hot end provides the liquified solder to the terminal and to the exposed portion of the wire. The apparatus includes a first heating device to heat the terminal and the exposed portion of the wire to enable a flow of the liquified solder onto the terminal and the exposed portion of the wire.

### BRIEF DESCRIPTION OF THE DRAWINGS

The embodiments of the present disclosure are pointed out with particularity in the appended claims. However, other features of the various embodiments will become more apparent and will be best understood by referring to the following detailed description in conjunction with the accompanying drawings in which:

FIG. 1 depicts an apparatus for providing an automated soldering process in accordance to one embodiment; and

FIG. 2 depicts a process for providing the automated soldering process in accordance to one embodiment.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

The embodiments of the present disclosure generally provide for a plurality of circuits or other electrical devices. All references to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microcontrollers, a graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a computer-program that is embodied in a non-transitory computer readable medium programmed to perform any number of the functions as disclosed.

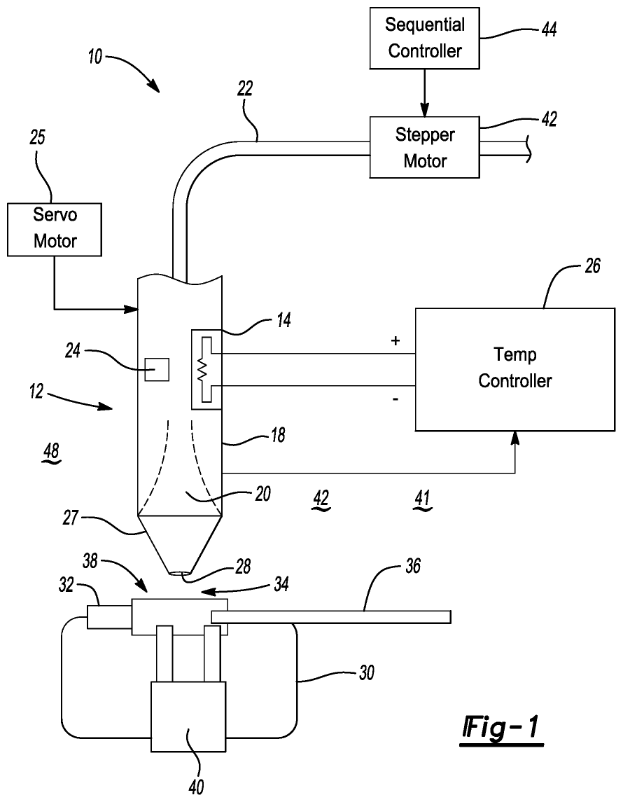

FIG. 1 depicts an apparatus 10 for providing an automated soldering process in accordance to one embodiment. The apparatus 10 forms a terminal crimping machine. The apparatus includes a solder head 12 (hereafter “hot end”) for applying solder 22 to a terminal 32 and to an exposed portion 34 of a wire 36. In one example, the hot end 12 may be similar to a hot end that is used in connection with a three-dimensional printer. The hot end 12 includes a resistive heater 14 and at least one thermocouple 24. The hot end 12 generally includes a metallic or steel casing 18 that forms an exterior portion thereof. The casing 18 defines a cavity (or reservoir) 20 for collecting the solder 22. The hot end 12 includes at least one thermocouple 24 positioned on the casing 18. A temperature controller 26 is electrically coupled to the resistive heater 14. It is recognized that the resistive heater 14 includes a resistor that is thermally active in response to receiving a voltage from the temperature controller 26. The resistive heater 14 applies thermal energy to the solder 22 thereby causing the solder 22 to heat and to flow from an opening 28 of the solder head 12 based on the voltage provided by the temperature controller 26. The casing 18 includes a nozzle 27 that defines the opening 28.

The apparatus 10 further includes a terminal fixture 30. A terminal 32 is placed on the terminal fixture 30 to receive the exposed portion 34 of the wire 36. The terminal 32 and the exposed portion 34 of the wire 36 receive the solder 22 from the hot end 12 when positioned on the terminal fixture 30. It is recognized that the terminal 32 may be one of a plurality of terminals that are assembled together on a terminal reel (not shown). It is further recognized that the exposed portion 34 of the wire 36 includes copper strands (or copper filaments) that are collected together. In general, the terminal 32 may be a male or female terminal and generally includes an opening to receive the exposed portion 34 of the wire 36. The terminal 32 and the exposed portion 34 of the wire 36 form an interface 38 for receiving the solder 22 in liquid form to fixedly attach the terminal 32 to the exposed portion 34 when the solder 22 cools.

The terminal fixture 30 includes a resistive heating device 40. The resistive heating device 40 may be similar to the resistive heater 14 positioned on the hot end 12 and includes a resistor (not shown) that generates thermal energy in response to a voltage. A separate temperature controller 41 may apply the voltage to the resistive heating device 40 such that the resistive heating device 40 generates thermal energy at a predetermined temperature to assist in providing a flow of the solder 22 from the hot end 12 and onto the terminal 32 and the exposed portion 34 of the wire 36. The resistive heating device 40 is also positioned below the terminal 32 to assist in providing the flow of the solder 22 onto the terminal 32 and onto the exposed portion 34 of the wire 36. In this case, the resistive heating device 40 applies thermal energy to the interface 38 to enable the solder 22 to flow to the terminal 32 and to a grouping of copper filaments that comprise the exposed portion 34 of the wire 36. The resistive heating device 40 enables the solder 22 to cover more surface area of the terminal 32 and the exposed portion 34 of the wire 36. After the hot end 12 applies the solder 22, the solder 22 cools thereby forming a mechanical joint with the terminal 32 and the exposed portion 34 of the wire 36. It is recognized that the terminal 32 may be crimped to the exposed portion 34 prior to the hot end 12 applying the solder 22 to the terminal 32 and the exposed portion 34 of the wire 36.

The resistive heating device 40 assists in maintaining an adequate volumetric flow rate of the solder 22 while the nozzle 27 dispenses the solder 22 onto the terminal 32 and the exposed portion 34 of the wire 36. In addition, the diameter of the opening 28 and the nozzle 27 also assist in maintaining a high volumetric flow rate of the solder 22 onto the terminal 32 and the exposed portion 34 of the wire 36.

A stepper motor 42 is provided to control the amount of solder 22 that is applied to the hot end 12 and later to the terminal 32 and to the exposed portion 34 of the wire 36. A sequential controller 44 controls the stepper motor 42 to linearly feed the solder 22 to the hot end 12 to control the proper amount of solder 22 from the hot end 12 to the terminal 32 and the exposed portion 34 of the wire 36. This condition enables the apparatus 10 to provide the appropriate amount of solder 22 to wires of different cross sections or gauges. In one example, the apparatus 10 can apply approximately 0.01 grams of solder 22 onto the terminal 32 and to the exposed portion 34 of the wire 36. Further, this condition enables the apparatus 10 to provide the appropriate amount of solder 22 to wires having a diameter 0.08-0.13 mm². Conventional systems have been unable to solder wires to terminals at this particular diameter for a wire. In addition, conventional systems have not been able to provide the proper amount of solder to a terminal and wire diameter of this size. It is recognized that since the apparatus 10 can apply an adequate amount of solder 22 to smaller gauge wires, the apparatus 10 can also apply the proper amount of solder 22 to larger gauge wires. A servo motor 25 is operably coupled to the hot end 12 to move the hot end 12 in an x, y, and z axis (or orientation) with respect to the position of the terminal fixture 30 when applying the solder 22 to the terminal 32 and to the exposed portion 34 of the wire 36. A controller (not shown) may control the servo motor 25 to move the hot end 12 to a desired location for applying the solder 22 to the terminal 32 and to the exposed portion 34 of the wire 36.

As noted above, in order to precisely control the amount of solder 22 dispensed per application cycle, the stepper motor 42 controls the linear feeding of the solder 22 into the hot end 12. This condition is directly related to the amount of solder 22 that is dispensed onto the terminal 32 and the exposed portion 34 of the wire 36. The stepper motor 42 generally includes a gear or rotor (not shown) surrounded by coils (not shown). As the coils are energized, this condition causes the rotor to rotate about an axis at predetermined angles or steps. The sequential controller 44 controls the rotor to rotate at various steps by selectively energizing the coils. For example, the sequential controller 44 applies power to each coil in the stepper motor 42 with a proper sequence.

When setting up the apparatus 10 for the soldering operation, the appropriate amount of solder 22 to be dispensed from the hot end 12 to the terminal 32 and the exposed portion 34 of the wire 36 may be established through testing. Once the appropriate amount of solder 22 has been established for a particular application, the sequential controller 44 may be programmed to repeatably provide the appropriate amount of solder at the specific point which is required. The sequential controller 44 achieves this by advancing the stepper motor 42 (e.g., the advancing the rotor) incrementally the appropriate number of degrees, and may then reverse the rotor for a specific number of degrees to precisely control the amount of solder 22 which is linearly fed into the hot end 12. Such an incremental advance at the appropriate number of degrees and reversal for a specific number of degrees generally corresponds to a predetermined number of degrees. Thus, the sequential controller 44 may control the stepper motor 42 to move the solder 22 to the hot end 12 based on the predetermined number of degrees. The sequential controller 44 may also control the stepper motor 42 to retract so that additional solder 22 is not liquefied at the hot end 12 causing unpredictability in the process.

As noted above, the temperature controller 26 is electrically coupled to the thermocouple 24 positioned on the casing 18 of the solder head 12. The thermocouple 24 provides a signal indicative of a temperature of the solder 22 within the reservoir 20 to the temperature controller 26. If the temperature controller 26 determines that a temperature of the solder 22 exceeds a predetermined temperature threshold, the temperature controller 26 may disable the resistive heater 14 and/or activate a cooling fan 48 to allow the solder in the reservoir 20 to cool to a temperature that is below the predetermined temperature threshold. In one example, the temperature controller 26 may increase the speed of the cooling fan 48 to cool the solder 22 after determining that the temperature of the solder 22 exceeds the predetermined temperature threshold. The cooling fan 48 is generally orientated to provide the cool air to the casing 18. If the temperature controller 26 determines that the temperature of the solder 22 is below the predetermined temperature threshold, the temperature controller 26 continues to control the resistive heater 14 to heat the solder 22 to a desired temperature to enable an adequate level of flow from the casing 18. It is recognized that the temperature controller 26 may also deactivate the cooling fan 48. Alternatively, the temperature controller 26 may also decrease the speed of the cooling fan 48 to enable the solder 22 to warm up to the predetermined temperature threshold.

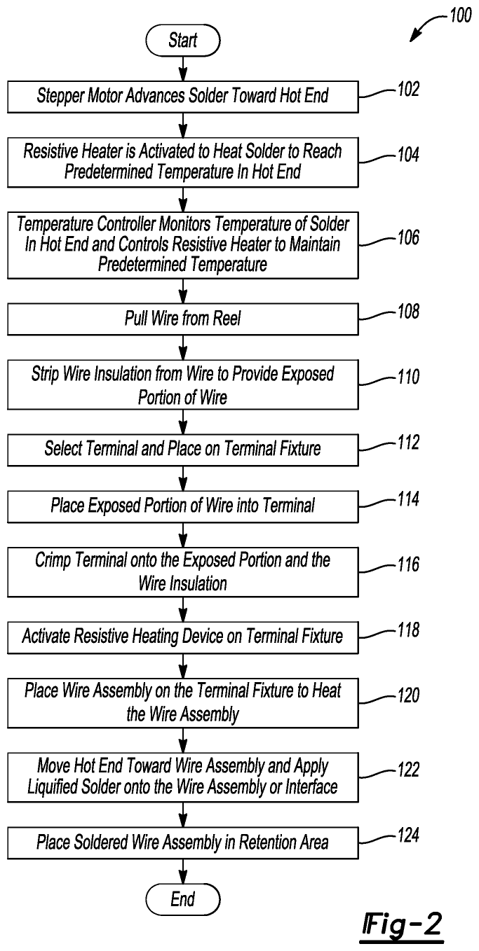

FIG. 2 depicts a process 100 for providing the automated soldering process in accordance to one embodiment. It is recognized that various operations noted below may be performed in parallel with one another. In addition, the sequence of the operations noted below may be different than the order in which the operations are set forth.

In operation 102, the stepper motor 42 advances the solder 22, under the control of the sequential controller 44, to the hot end 12.

In operation 104, the temperature controller 26 activates the resistive heater 14 of the hot end 12 to heat the solder 22 to reach a predetermined temperature within the reservoir 20 of the hot end 12.

In operation 106, the temperature controller 26 monitors the temperature of the solder 22 within the reservoir 20 of the hot end 12 and controls the resistive heater 14 to provide the solder 22 at the predetermined temperature.

In operation 108, the wire 36 is pulled from a reel.

In operation 110, a wire stripper strips wire insulation from the wire 36 to provide the exposed portion 34 of the wire 36.

In operation 112, the apparatus 10 selects the terminal 32 and places the terminal 32 within a cavity (or terminal support structure) formed on the terminal fixture 30.

In operation 114, the apparatus 10 places the exposed portion 34 of the wire 36 into the terminal 32.

In operation 116, the apparatus 10 crimps the terminal 32 onto the exposed portion 34 of the wire 36 and onto an insulated portion of the wire 36.

In operation 118, the separate temperature controller 41 activates the resistive heating device 40 on the terminal fixture 30 to heat the wire assembly (e.g., the terminal 32 and the exposed portion 34 of the wire 36).

In operation 120, the resistive heating device 40 heats the exposed portion 34 of the wire 36.

In operation 122, the servo motor 25 moves the hot end 12 toward the terminal 32 and the exposed portion 34 of the wire 36. The hot end 12 then applies the solder 22 onto the terminal 32 and the exposed portion 34 of the wire 36). As noted above, the servo motor 25 may move the hot end 12 in any of the three axes. In this case, the heat from the resistive heating device 40 enables the solder 22 to cover more surface area of the terminal 32 and the exposed wire 34 as the solder 22 moves within the filaments of the copper wires that form the exposed portion 34 and onto the terminal 32.

In operation 124, the apparatus 10 places the soldered wire assembly in a retention area.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. An apparatus for an automated soldering process comprising:
a stepper motor to provide solder;
a hot end including a casing to heat the solder and to provide liquified solder to a terminal and to an exposed portion of a wire;
a terminal fixture to support the terminal and the exposed portion of a wire while the hot end provides the liquified solder to the terminal and to the exposed portion of the wire; and
a first heating device to heat the terminal and the exposed portion of the wire to enable a flow of the liquified solder onto the terminal and the exposed portion of the wire.

2. The apparatus of claim 1, wherein the first heating device is positioned on the terminal fixture to heat the terminal and the exposed portion of the wire.

3. The apparatus of claim 2, wherein the first heating device is a first resistive heating device.

4. The apparatus of claim 1 further comprising a sequential controller configured to control the stepper motor including a rotor to rotate at a predetermined number of degrees to provide the solder to the hot end.

5. The apparatus of claim 1, wherein the hot end provides a predetermined amount of the liquified solder to the terminal and to the exposed portion of the wire.

6. The apparatus of claim 1 further comprising at least one thermocouple positioned on the casing to provide a signal indicative of a temperature of the solder within the casing.

7. The apparatus of claim 6 further comprising a second heating device positioned on the casing to heat the solder to provide the liquified solder.

8. The apparatus of claim 7 further comprising a temperature controller configured to receive the signal and to control the second heating device to heat the solder to reach a predetermined temperature based on the signal.

9. The apparatus of claim 1, wherein the wire has a diameter of 0.08-0.13 mm².

10. An apparatus for an automated soldering process comprising:
a stepper motor to provide solder;
a hot end to heat the solder and to provide liquified solder to a terminal and to an exposed portion of a wire;
a terminal fixture to support the terminal and the exposed portion of a wire while the hot end provides the liquified solder to the terminal and to the exposed portion of the wire; and
a first heating device to heat the terminal and the exposed portion of the wire to enable a flow of the liquified solder onto the terminal and the exposed portion of the wire.

11. The apparatus of claim 10, wherein the first heating device is positioned on the terminal fixture to heat the terminal and the exposed portion of the wire.

12. The apparatus of claim 11, wherein the first heating device is a first resistive heating device.

13. The apparatus of claim 10 further comprising a sequential controller configured to control the stepper motor including a rotor to rotate at a predetermined number of degrees to provide the solder to the hot end.

14. The apparatus of claim 10, wherein the hot end provides a predetermined amount of the liquified solder to the terminal and to the exposed portion of the wire.

15. The apparatus of claim 10 further comprising at least one thermocouple positioned on the hot end to provide a signal indicative of a temperature of the solder within the hot end.

16. The apparatus of claim 15 further comprising a second heating device positioned on the hot end to heat the solder to provide the liquified solder.

17. The apparatus of claim 16 further comprising a temperature controller configured to receive the signal and to control the second heating device to heat the solder to reach a predetermined temperature based on the signal.

18. The apparatus of claim 10, wherein the wire has a diameter of 0.08-0.13 mm².

19. An apparatus for an automated soldering process comprising:
a hot end including a casing to heat the solder and to provide liquified solder to a terminal and to an exposed portion of a wire;
a terminal fixture to support the terminal and the exposed portion of a wire while the hot end provides the liquified solder to the terminal and to the exposed portion of the wire; and
a first heating device to heat the terminal and the exposed portion of the wire to enable a flow of the liquified solder onto the terminal and the exposed portion of the wire.

20. The apparatus of claim 19 further comprising a stepper motor including a rotor configured to rotate at a predetermined number of degrees to provide the solder to the hot end.
